(19) United States
(12) Patent Application Publication
(10) Pub. No.: US 2011/0238337 A1
(43) Pub. Date: Sep. 29, 2011

(54) MEASUREMENT APPARATUS, MEASUREMENT METHOD, TEST APPARATUS AND RECORDING MEDIUM

(75) Inventor: Norio Kobayashi, Gunma (JP)

(73) Assignee: ADVANTEST CORPORATION, Tokyo (JP)

(21) Appl. No.: 13/018,124

(22) Filed: Jan. 31, 2011

(30) Foreign Application Priority Data
Mar. 23, 2010 (JP) 2010-066924

(51) Int. Cl. G06F 19/00; G01R 31/02

(52) U.S. Cl. 702/58; 324/537

(57) ABSTRACT

Provided is a measurement apparatus for measuring an error of a modulation apparatus that outputs an output signal obtained as a sum of a first modulated signal output from a first modulating section and a second modulated signal output from a second modulating section. The measurement apparatus comprises a control section that causes the modulation apparatus to output an output signal having at least three different signal points; a measuring section that measures power of the output signal for each of the at least three signal points; and a calculating section that calculates at least one of an amplitude error and a phase error between the first modulated signal and the second modulated signal, based on the power of the output signal for each of the at least three signal points.

### BACKGROUND

1. Technical Field

The present invention relates to a measurement apparatus, a measurement method, and a recording medium.

2. Related Art

A conventional LINC circuit is known that outputs a modulated signal, as shown in Non-Patent Documents 1 to 5, for example. The LINC circuit uses two IQ modulators to generate two modulated signals with different phases and fixed amplitudes, and outputs the desired amplitude and phase signals by adding together the two modulated signals generated by the two IQ modulators. This type of LINC circuit can output a signal with a high amplitude and low distortion, regardless of the linearity of the amplifier at the output stage.
Non-Patent Document 1: Lars Sundström, “Spectral Sensitivity of LINC Transmitters to Quadrature Modulator Misalignments”, IEEE TRANSACTIONS ON VEHICULAR TECHNOLOGY, VOL. 49, NO. 4, JULY 2000
Non-Patent Document 2: Fernando J. Casadevall, and Antonio Valdovinos, “Performance Analysis of QAM Modulations Applied to the LINC Transmitter”, IEEE TRANSACTIONS ON VEHICULAR TECHNOLOGY, VOL. 42, NO. 4, NOVEMBER 1993
Non-Patent Document 3: Gwenael Poitau, Ahmed Birafane and Ammar Kouki, “Experimental Characterization of LINC Outphasing Combiners'Efficiency and Linearity”, IEEE Radio and Wireless Conference, 2004
Non-Patent Document 4: Young Yuri Woo, Jaehyok Yi, Youngoo Yang, and Bumman Kim, “SDR Transmitter Based on LINC Amplifier with Bias Control”, Microwave Symposium Digest, 2003 IEEE MTT-S International
Non-Patent Document 5: Xuejun Zhang, Lawrence E. Larson, and Peter Asbeck, “Design of Linear RF Outphasing Power Amplifiers”, (USA), Artech House, 2003

However, the LINC circuit cannot output an accurate modulated signal if there is an amplitude error or a phase error between the two IQ modulators. Furthermore, it is difficult to easily and accurately measure the amplitude error and the phase error between the two IQ modulators.

### SUMMARY

Therefore, it is an object of an aspect of the innovations herein to provide a measurement apparatus, a measurement apparatus, and a recording medium, which are capable of overcoming the above drawbacks accompanying the related art. The above and other objects can be achieved by combinations described in the independent claims. According to a first aspect related to the innovations herein, provided is a measurement apparatus for measuring an error of a modulation apparatus that outputs an output signal obtained as a sum of a first modulated signal output from a first modulating section and a second modulated signal output from a second modulating section. The measurement apparatus comprises a control section that causes the modulation apparatus to output an output signal having at least three different signal points; a measuring section that measures power of the output signal for each of the at least three signal points; and a calculating section that calculates at least one of an amplitude error and a phase error between the first modulated signal and the second modulated signal, based on the power of the output signal for each of the at least three signal points. Also provided are a measurement method and a recording medium.

The summary clause does not necessarily describe all necessary features of the embodiments of the present invention. The present invention may also be a sub-combination of the features described above.

### BRIEF DESCRIPTION OF THE DRAWINGS

FIG. 1 shows configurations of a modulation apparatus 10 and a measurement apparatus 40 according to an embodiment of the present invention.

FIG. 2 shows exemplary phases and amplitudes of the output signal (Sout), the first modulated signal (S₁), and the second modulated signal (S₂) in the present embodiment.

FIG. 3 shows an exemplary method for calculating the two phases (θ₁, θ₂) to be set in the first modulating section 22 and the second modulating section 24, when a designated amplitude (R) and designated phase (θ) are supplied thereto.

FIG. 4 shows a model of the amplitude error (gₑᵣᵣ) and the phase error (θₑᵣᵣ) between the first modulating section 22 and the second modulating section 24.

FIG. 5 shows a flow of the error calculation process performed by the measurement apparatus 40 according to the present embodiment.

FIG. 6 shows exemplary vectors output as a result of the first error calculation process.

FIG. 7 shows exemplary vectors output as a result of the second error calculation process.

FIG. 8 shows a magnified view near the origin point shown in FIG. 7.

FIG. 9 shows exemplary vectors output as a result of the third error calculation process.

FIG. 10 shows an example of a hardware configuration of a computer 1900 according to the present embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

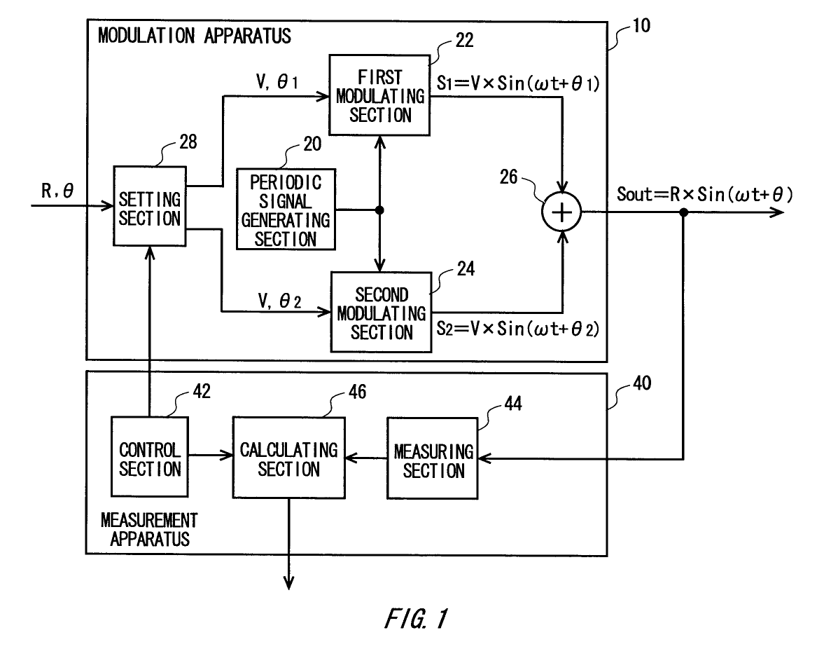

FIG. 1 shows configurations of a modulation apparatus 10 and a measurement apparatus 40 according to an embodiment of the present invention. The modulation apparatus 10 outputs an output signal (Sout) with a prescribed frequency and a designated amplitude (R) and designated phase (θ) designated from the outside. The modulation apparatus 10 is an example of a so-called LINC (linear amplification using non-linear components) circuit.

The modulation apparatus 10 includes a periodic signal generating section 20, a first modulating section 22, a second modulating section 24, an adding section 26, and a setting section 28. The periodic signal generating section 20 generates a periodic signal with a predetermined frequency. For example, the periodic signal generating section 20 may generate a sinusoidal signal (Sin ωt) with an angular frequency (ω) as the periodic signal. The periodic signal generating section 20 may generate, as the periodic signal, a square-wave signal that includes the sinusoidal signal (Sin ωt) with angular frequency (ω) as a primary component.

The first modulating section 22 outputs a first modulated signal (S₁) with a first phase (θ₁) set by the setting section 28 and a predetermined fixed amplitude (V). The first modulating section 22 may output the first modulated signal (S₁=V×Sin(ωt+θ₁)) with the first phase (θ₁) and the fixed amplitude (V) by performing orthogonal modulation on the periodic signal (Sin ωt) generated by the periodic signal generating section 20.

The second modulating section 24 outputs a second modulated signal (S₂) with a second phase (θ₂) set by the setting section 28, a predetermined fixed amplitude (V), and a frequency equal to the frequency of the first modulated signal (S₁). The second modulating section 24 may output the second modulated signal (S₂=V×Sin(ωt+θ₂)) with the second phase (θ₂) and the fixed amplitude (V) by performing orthogonal modulation on the periodic signal (Sin ωt) generated by the periodic signal generating section 20.

The adding section 26 adds together the first modulated signal (S₁) with fixed amplitude output from the first modulating section 22 and the second modulated signal (S₂) with fixed amplitude output from the second modulating section 24, and outputs the result as the output signal (Sout=V×Sin(ωt+θ₁)+V×Sin(ωt+θ₂)).

The setting section 28 receives the designated amplitude (R) and the designated phase (θ) from the outside. The setting section 28 calculates the first phase (θ₁) to be set in the first modulating section 22 and the second phase (θ₂) to be set in the second modulating section 24, based on the designated amplitude (R) and the designated phase (θ). The setting section 28 sets the calculated first phase (θ₁) in the first modulating section 22 and sets the calculated second phase (θ₂) in the second modulating section 24. The method of calculating the first phase (θ₁) and the second phase (θ₂) performed by the setting section 28 is described in detail further below.

The modulation apparatus 10 is supplied with data that indicates the designated amplitude (R) and the designated phase (θ) for each predetermined sampling rate. The modulation apparatus 10 can output the output signal (Sout=R×Sin(ωt+θ)) having the designated amplitude (R) and the designated phase (θ) for each sampling rate.

The measurement apparatus 40 measures the error of the modulation apparatus 10 by performing a calibration or the like. More specifically, the measurement apparatus 40 measures at least one of the amplitude error and the phase error between the first modulating section 22 and the second modulating section 24.

The measurement apparatus 40 includes a control section 42, a measuring section 44, and a calculating section 46. The control section 42 causes the modulation apparatus 10 to output an output signal (Sout) having at least three different signal points. For example, the control section 42 may cause the modulation apparatus 10 to output an output signal (Sout) having at least four signal points in which the amplitudes of the first modulated signal (S1) and the second modulated signal (S2) are set to be predetermined values and the phases thereof are set to obtain different phase differences. As another example, the control section 42 may cause the modulation apparatus 10 to output an output signal (Sout) having at least three signal points in which the phase difference between the first modulated signal (S₁) and the second modulated signal (S₂) is set to be a predetermined value and the amplitudes thereof are set to be different values.

The measuring section 44 measures the power of the output signal (Sout) having at least three or at least four signal points output from the modulation apparatus 10. The calculating section 46 calculates at least one of the amplitude error or the phase error between the first modulated signal (S₁) and the second modulated signal (S₂), based on the power calculated for the output signal (Sout) with at least three or at least four signal points. The method for calculating the amplitude error and the phase error is described in detail further below.

The measurement apparatus 40 calculates at least one of the amplitude error and the phase error between the first modulating section 22 and the second modulating section 24 within the measurement apparatus 40, based on the power of the output signal (Sout). As a result, the measurement apparatus 40 need not measure the phase or amplitude of the output signal (Sout), and can therefore easily and accurately calculate the amplitude error and the phase error.

The measurement apparatus 40 may further include an adjusting section that corrects the amplitude error and the phase error of the modulation apparatus 10 based on the calculated amplitude error and phase error. The adjusting section may adjust the hardware parameters, such as the gain or the delay amount of the amplifiers, in the first modulating section 22 and the second modulating section 24 of the modulation apparatus 10, or may adjust coefficients for correcting the values of the amplitude and phase input to the first modulating section 22 and the second modulating section 24.

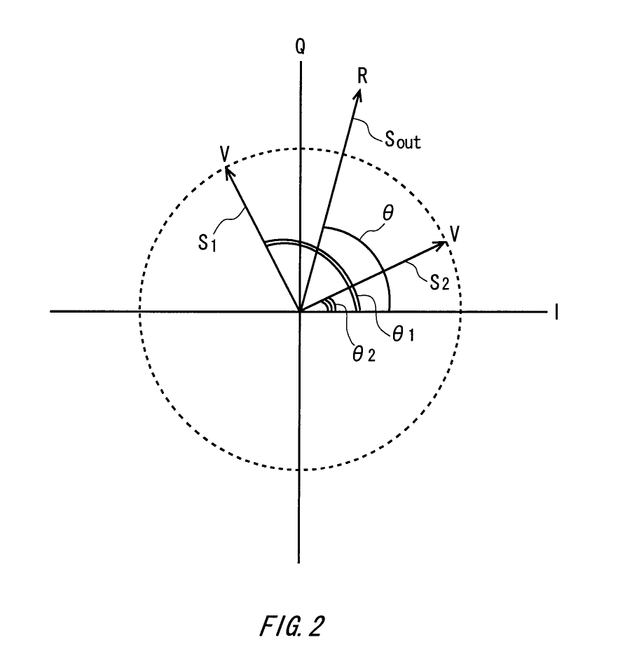

FIG. 2 shows exemplary phases and amplitudes of the output signal (Sout), the first modulated signal (S₁), and the second modulated signal (S₂) in the present embodiment. When the phase of the periodic signal generated from the periodic signal generating section 20 is zero, the first modulating section 22 and the second modulating section 24 output a first modulated signal (S₁) and a second modulated signal (S₂) such as shown in FIG. 2.

Specifically, the first modulating section 22 outputs the first modulated signal (S₁) with a fixed amplitude V and a first phase θ₁. The second modulating section 24 outputs the second modulated signal (S₂) with a fixed amplitude V and a second phase θ₂.

The adding section 26 outputs the output signal (Sout) as the vector sum of the first modulated signal (S₁) and the second modulated signal (S₂). In other words, the phase (θ) of the output signal (Sout) becomes the center (Ph(θ₁+θ₂)/2) of the first phase θₜ and the second phase θ₂. The amplitude (R) of the output signal (Sout) is obtained as the sum of the cosine component (V×Cos(Ph(θ₁−Ph((θ₁+θ₂)/2)))) of the first modulated signal (S₁) and the cosine component (V×Cos(Ph(θ₂−Ph((θ₁+θ₂)/2)))) of the second modulated signal (S₂), when the center (Ph(θ₁+θ₂)/2) of the first phase θ₁ and the second phase θ₂ is used as a reference. Here, y=Ph(x) represents an function in which an input x returns a y value of −180°≦θ≦180°. This function is the same in other expressions.

In FIG. 2, the first phase θ₁ is shown as being ahead of the phase (θ) of the output signal (Sout) and the second phase θ₂ is shown as being behind the phase (θ) of the output signal (Sout), but the phases are not limited to this. In other words, the first phase θ₁ may be behind the phase (θ) of the output signal (Sout) and the second phase θ₂ may be ahead of the phase (θ) of the output signal (Sout),

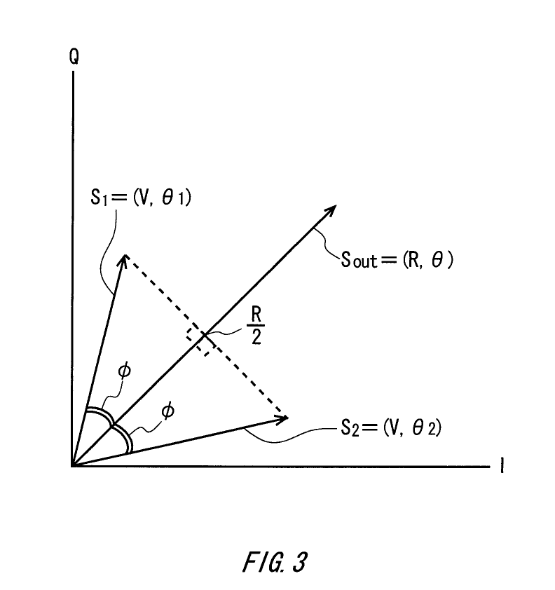

FIG. 3 shows an exemplary method for calculating the two phases (θ₁, θ₂) to be set in the first modulating section 22 and the second modulating section 24, when a designated amplitude (R) and designated phase (θ) are supplied thereto. Upon receiving the designated amplitude (R) and designated phase (θ) from the outside, the setting section 28 calculates the adjustment phase (φ) as shown below in Expression 1.

φ=cos⁻¹((R/2)/V) (1)

In other words, the setting section 28 calculates the adjustment phase (φ) to be the arc-cosine (cos⁻¹((R/2)/V)) of a ratio of half the designated amplitude (R) to the predetermined fixed amplitude (V). Next, the setting section 28 calculates the two phases (θ₁, θ₂) to be set for the first modulating section 22 and the second modulating section 24, as shown below in Expressions 2 and 3.

θ₁=Ph(θ+φ) (2)

θ₂=Ph(θ−φ) (3)

In other words, the setting section 28 calculates the phase (θ₁=Ph(θ+φ)) that is the sum of the designated phase (θ) and the adjustment phase (φ), which is the phase reached by advancing from the designated phase by the adjustment phase (φ). The setting section 28 calculates the phase (θ₂=Ph(θ−φ)) that is obtained by subtracting the adjustment phase (φ) from the designated phase (θ), which is the phase reached by delaying by the adjustment phase (φ) from the designated phase.

The setting section 28 allocates one of the two calculated phases (θ₁, θ₂) as the first modulated signal (S₁) and allocates the other as the second modulated signal (S₂). In the example of FIG. 3, the phase reached by advancing by the adjustment phase (φ) from the designated phase is set as the first modulated signal (S₁) and the phase reached by delaying by the adjustment phase (φ) from the designated phase is set as the second modulated signal, but opposite allocation may be used instead.

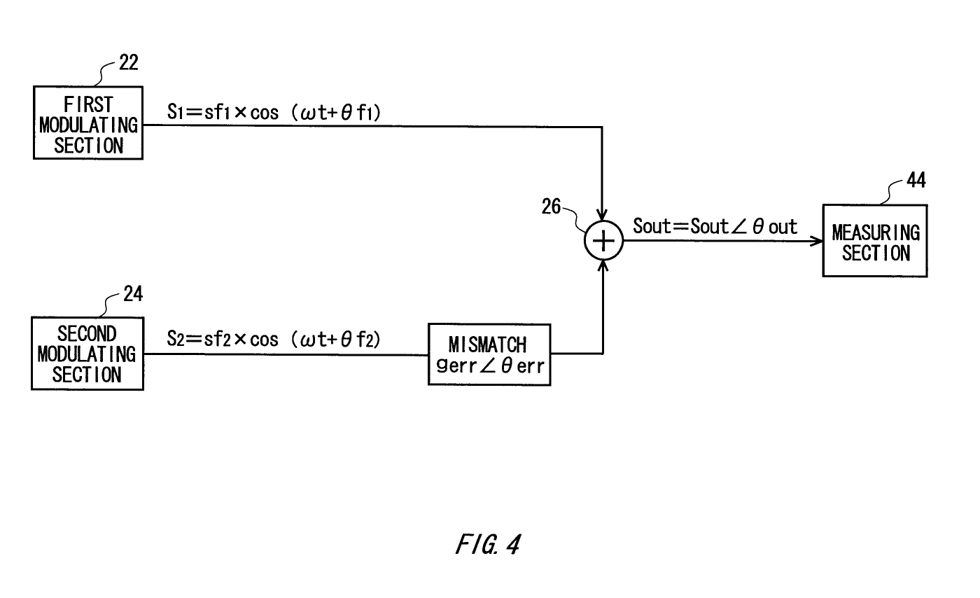

FIG. 4 shows a model of the amplitude error (gₑᵣᵣ) and the phase error (θₑᵣᵣ) between the first modulating section 22 and the second modulating section 24. In the present embodiment, the measurement apparatus 40 calculates the amplitude error (gₑᵣᵣ) and the phase error (θₑᵣᵣ) in a model in which a mismatch component is contained in the path between the second modulating section 24 and the adding section 26. When correcting a mismatch component between the first modulating section 22 and the second modulating section 24, the measurement apparatus 40 may correct the path on the first modulating section 22 side, correct the path on the second modulating section 24 side, or correct the paths on both the first modulating section 22 and second modulating section 24 sides.

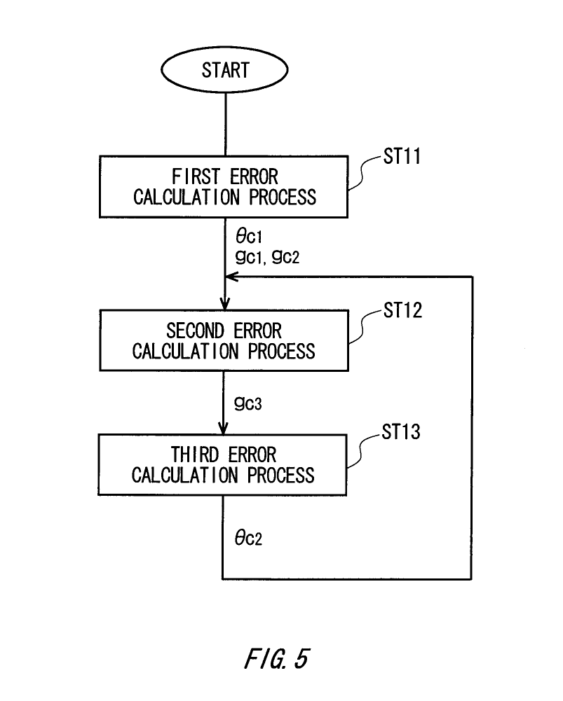

FIG. 5 shows a flow of the error calculation process performed by the measurement apparatus 40 according to the present embodiment. The measurement apparatus 40 calculates the amplitude error and the phase error of the modulation apparatus 10 according to the flow shown in FIG. 5.

First, at step ST11, the measurement apparatus 40 performs a first error calculation process. In the first error calculation process, the measurement apparatus 40 may cause the modulation apparatus 10 to output an output signal (Sout) having four signal points in which the amplitudes of the first modulated signal (S₁) and the second modulated signal (S₂) are set to predetermined values and the phases thereof are set to obtain different phase differences.

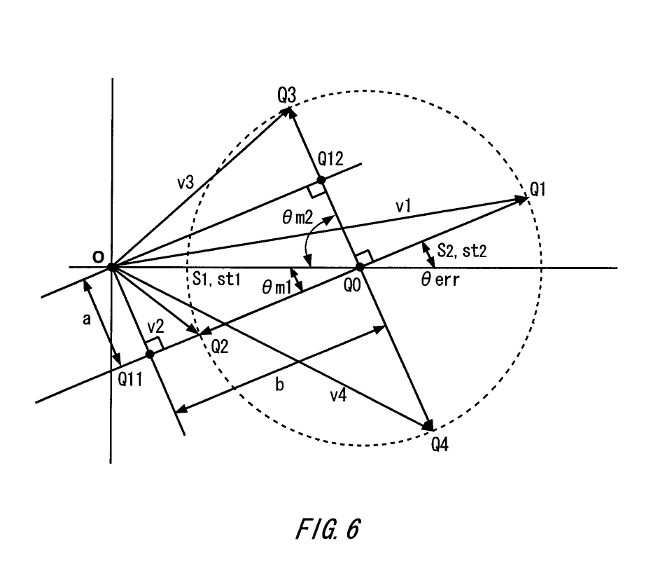

The measurement apparatus 40 calculates a first phase error estimation value θ_{c1} and at least one of a first amplitude error estimation value g_{c1} and a second amplitude error estimation value g_{c2}, based on the power of the output signal (Sout) having at least four signal points. A more detailed example of the calculation method used in step ST11 is provided in FIG. 6.

At step ST12, the measurement apparatus 40 performs a second error calculation process using the first phase error estimation value θ_{c1} and at least one of the first amplitude error estimation value g_{c1} and the second amplitude error estimation value g_{c2}. In the second error calculation process, the measurement apparatus 40 causes the modulation apparatus 10 to output an output signal (Sout) having at least three signal points in which predetermined phases and different amplitudes are set for the first modulated signal (S₁) and the second modulated signal (S₂).

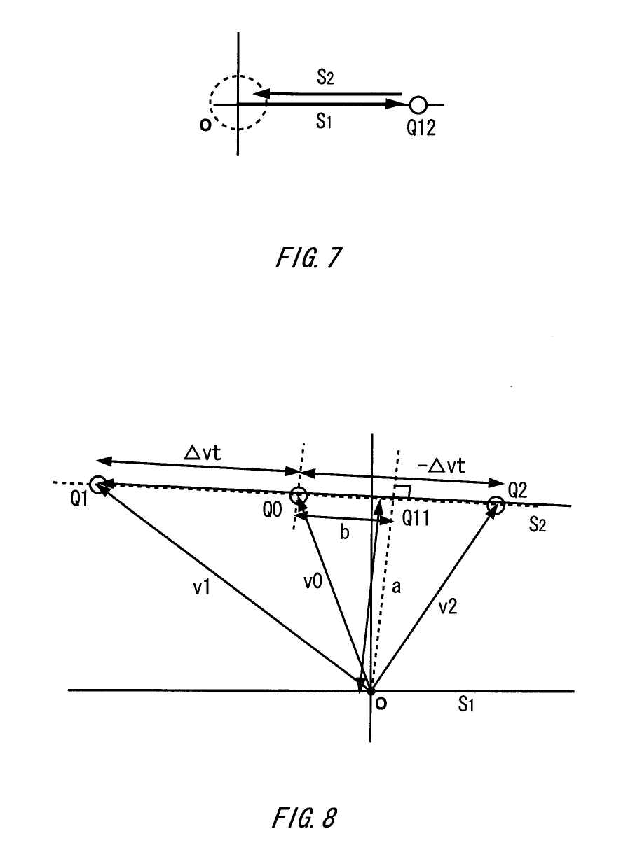

The measurement apparatus 40 calculates a third amplitude error estimation value g_{c3}, based on the power of the output signal (Sout) having at least three signal points. A more detailed example of the calculation method used in step ST12 is provided in FIGS. 7 and 8.

At step S13, the measurement apparatus 40 performs a third error calculation process using the first phase error estimation value θ_{c1} and the third amplitude error estimation value g_{c3}. In the third error calculation process, the measurement apparatus 40 causes the modulation apparatus 10 to output an output signal (Sout) having at least three signal points in which predetermined amplitudes and different phase differences are set for the first modulated signal (S₁) and the second modulated signal (S₂).

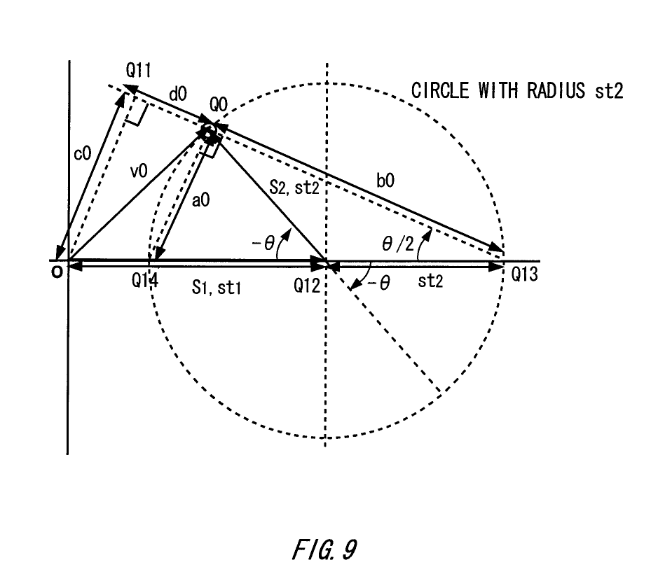

The measurement apparatus 40 calculates a second phase error estimation value θ_{c2}, based on the power of the output signal (Sout) having at least three signal points. A more detailed example of the calculation method used in step ST13 is provided in FIG. 9.

When step S13 is finished, the measurement apparatus 40 repeats a process loop including steps S12 and S13. In steps S12 and S13 of this process loop, the measurement apparatus 40 performs error calculation processes using the third amplitude error estimation value g_{c3} calculated in the second error calculation process performed immediately therebefore and the second phase error estimation value θ_{c2} calculated in the third error calculation process performed immediately therebefore.

As a result, the measurement apparatus 40 can gradually approximate the amplitude error estimation value and the phase error estimation value to their true values. For example, the measurement apparatus 40 may leave the loop when the number of process loop repetitions including steps S12 and S13 reaches a reference number. Instead, the measurement apparatus 40 may leave the loop when the third amplitude error estimation value g_{c3} and the second phase error estimation value θ_{c2} each converge on a constant value.

The measurement apparatus 40 outputs, as the calculation results for the amplitude error and the phase error, the third amplitude error estimation value g_{c3} and the second phase error estimation value θ_{c2} at the time when the loop is exited. The timing at which the loop is exited may be after step ST12 or after step ST13.

As described above, the measurement apparatus 40 performs the above processes during a calibration or the like. As a result, the measurement apparatus 40 can accurately calculate the amplitude error and the phase error of the modulation apparatus 10.

The measurement apparatus 40 may perform the processes of steps ST12 and ST13 in the opposite order. In this case, at the first performance of step ST13, the measurement apparatus 40 performs the third error calculation process using the first phase error estimation value θ_{c1} and at least one of the first amplitude error estimation value g_{c1} and the second amplitude error estimation value g_{c2} calculated during the error calculation process of step ST11. Furthermore, at the first performance of step ST12, the measurement apparatus 40 performs the second error calculation process using at least one of the first amplitude error estimation value g_{c1} and the second amplitude error estimation value g_{c2} calculated during the error calculation process of step ST11 and the second phase error estimation value θ_{c2} calculated during the error calculation process of step ST12.

FIG. 6 shows exemplary vectors output as a result of the first error calculation process. During the first error calculation process of step ST11, the control section 42, the measuring section 44, and the calculating section 46 of the measurement apparatus 40 perform the following processes, for example.

First, the control section 42 causes the modulation apparatus 10 to output an output signal (Sout) having four signal points in which the same predetermined amplitudes are set for the first modulated signal (S₁) and the second modulated signal (S₂) and the phases thereof are set to obtain phase differences of 0°, 180°, 90°, and 270°. The measuring section 44 measures the power of the output signal (Sout) for each of these four signal points.

The calculating section 46 calculates the phase error estimation value between the first modulated signal (S₁) and the second modulated signal (S₂) based on the power of the output signal (Sout) for each of the four signal points. More specifically, with p₁ representing the power of the output signal (Sout) output when the phase difference is set to 0°, p₂ representing the power of the output signal (Sout) output when the phase difference is set to 180°, p₃ representing the power of the output signal (Sout) output when the phase difference is set to 90°, and p₄ representing the power of the output signal (Sout) output when the phase difference is set to 270°, the calculating section 46 calculates the first phase error estimation value ƒ_{c1} according to Expressions 11 and 12 shown below.

$$\begin{matrix}{θ}_{c 1} = {θ}_{m 1} = \{ \begin{matrix}{tan}^{- 1} ( - \frac{A}{B} ) … B \geq 0 , A \geq 0 \\ {tan}^{- 1} ( - \frac{A}{B} ) + 180 … B < 0 \\ {tan}^{- 1} ( - \frac{A}{B} ) + 360 … B \geq 0 , A < 0\end{matrix} & ( 11 ) \\ {θ}_{c 1} = 90 - {θ}_{m 2} = \{ \begin{matrix}90 - {tan}^{- 1} ( \frac{B}{A} ) … A \geq 0 \\ 270 - {tan}^{- 1} ( \frac{B}{A} ) … A < 0\end{matrix} & ( 12 )\end{matrix}$$

The calculating section 46 performs the calculation using Expression 11 when |B|>|A| and performs the calculation using Expression 12 when |B|≦|A|. Furthermore, in Expressions 11 and 12, A and B can be calculated as shown by Expressions 13 and 14 below.

A=p₃−p₄ (13)

B=p₁−p₂ (14)

The calculating section 46 calculates the amplitude error estimation value between the first modulated signal (S₁) and the second modulated signal (S₂) based on the power of the output signal (Sout) for each of the four signal points. More specifically, with p₁ representing the power of the output signal (Sout) output when the phase difference is set to 0°, p₂ representing the power of the output signal (Sout) output when the phase difference is set to 180°, p₃ representing the power of the output signal (Sout) output when the phase difference is set to 90°, and p₄ representing the power of the output signal (Sout) output when the phase difference is set to 270°, the calculating section 46 calculates at least one of the first amplitude error estimation value g_{c1} and the second amplitude error estimation value g_{c2} according to Expressions 15 and 16 below.

$$\begin{matrix}{g}_{c 1} = \sqrt{1 + \frac{2}{\frac{D}{E} - 1}} & ( 15 ) \\ {g}_{c 2} = \sqrt{1 - \frac{2}{\frac{D}{E} + 1}} & ( 16 )\end{matrix}$$

In Expressions 15 and 16, D and E can be calculated as shown by Expression 17 below.

$$D = \frac{1}{4} ( {p}_{1} + {p}_{2} ) \\ E = \frac{1}{4} \sqrt{4 {p}_{1} {p}_{2} - {( {p}_{3} - {p}_{4} )}^{2}} \qquad ( 17 )$$

In this way, the measurement apparatus 40 can calculate the phase error and the amplitude error based on the power of an output signal with four signal points in which predetermined amplitudes and phases resulting in different phase differences are set for the first modulated signal (S₁) and the second modulated signal (S₂). As a result, the measurement apparatus 40 can measure the phase error and the amplitude error between the first modulating section 22 and the second modulating section 24 more accurately than a simple measuring device.

The following uses FIG. 6 to further describe the reason why the phase error can be calculated using Expressions 11 and 12.

In FIG. 6, Q0 represents the vector of the first modulated signal (S₁), sₜ₁ represents the amplitude of the first modulated signal (S₁) at the output end, and sₜ₂ represents the amplitude of the second modulated signal (S₂) at the output end.

In FIG. 6, the amplitude s_{f1} of the first modulated signal (S₁) at the input end is set to 1, the amplitude s_{f2} of the second modulated signal (S₂) at the input end is set to 1, the phase θ_{f1} of the first modulated signal (S₁) at the input end is set to 0°, and the phase θ_{f2} of the second modulated signal (S₂) at the input end is set to 0°, 180°, 90°, and 270°.

In FIG. 6, O-Q1 represents the vector of the output signal when θ_{f2}=0° and has an amplitude v₁, O-Q2 represents the vector of the output signal when θ_{f2}=180° and has an amplitude v₂, O-Q3 represents the vector of the output signal when θ_{f2}=90° and has an amplitude v₃, and O-Q4 represents the vector of the output signal when θ_{f2}=270° and has an amplitude v₄.

Furthermore, Q12 represents an intersection point between the line Q1-Q2 and a line descending orthogonally therefrom through the origin O, “b” represents the length of O-Q12, and “a” represents the length Q12-Q0.

Expressions 101 to 105 are derived from FIG. 6.

v₁²=a²+(b+sₜ₂)²=a²+b²+sₜ₂²+2bsₜ₂ (101)

v₂²=a²+(b−sₜ₂)²=a²+b²+sₜ₂²−2bsₜ₂ (102)

v₃²=b²+(a−sₜ₂)²=b²+a²+sₜ₂²−2asₜ₂ (103)

v₄²=b²+(a+sₜ₂)²=b²+a²+sₜ₂²+2asₜ₂ (104)

sₜ₁²=a²+b² (105)

Expressions 106 and 107 are derived from Expressions 101 to 104.

v₁²−v₂²=4bsₜ₂ (106)

v₃²−v₄²=−4asₜ₂ (107)

Based on Expressions 106 and 107, the phase differences θₘ₁ and θₘ₂ of the first modulated signal (S₁) and the second modulated signal (S₂) can be shown by Expression 108 and 109.

$$\begin{matrix}{θ}_{m 1} = {tan}^{- 1} \frac{a}{b} = {tan}^{- 1} ( - \frac{{v}_{3}^{2} - {v}_{4}^{2}}{{v}_{1}^{2} - {v}_{1}^{2}} ) & ( 108 ) \\ {θ}_{m 2} = {tan}^{- 1} \frac{b}{a} = {tan}^{- 1} ( - \frac{{v}_{1}^{2} - {v}_{2}^{2}}{{v}_{3}^{2} - {v}_{4}^{2}} ) & ( 109 )\end{matrix}$$

Accordingly, the phase error estimation value θₑᵣᵣ can be obtained as shown in Expression 110.

θ_{c1}=θₘ₁=90−θₘ₂ (110)

It should be noted that, although the arctangent is in a range from −90° to 90°, θ_{c1} is expressed in a range from 0° to 360°. Therefore, θ_{c1} can be calculated as shown in Expressions 111 and 112.

$$\begin{matrix}{θ}_{c 1} = {θ}_{m 1} = \{ \begin{matrix}{tan}^{- 1} ( - \frac{A}{B} ) … B \geq 0 , A \geq 0 \\ {tan}^{- 1} ( - \frac{A}{B} ) + 180 … B < 0 \\ {tan}^{- 1} ( - \frac{A}{B} ) + 360 … B \geq 0 , A < 0\end{matrix} & ( 111 ) \\ {θ}_{c 1} = 90 - {θ}_{m 2} = \{ \begin{matrix}90 - {tan}^{- 1} ( - \frac{B}{A} ) … A \geq 0 \\ 270 - {tan}^{- 1} ( - \frac{B}{A} ) … A < 0\end{matrix} & ( 112 )\end{matrix}$$

Expression 111 is used to calculate θ_{c1} when |B|>|A|, and Expression 112 is used to calculate θ_{c1} when |B|≦|A|. In Expressions 111 and 112, A and B can be calculated using Expressions 113 and 114.

A=v₃²−v₄² (113)

B=v₁²−v₂² (114)

Here, v₁² represents the power p₁ of the output signal when θ_{f2}=0°, v₂² represents the power p₂ of the output signal when θ_{f2}=180°, v₃² represents the power p₃ of the output signal when θ_{f2}=90°, and v₄² represents the power p₄ of the output signal when θ₂=270°.

In this way, the measurement apparatus 40 can calculate the phase error estimation value from Expressions 111 and 112. Furthermore, even when the overall amplitude of the output signal is multiplied by α, the value of θ_{c1} does not change because the numerator and denominator of A/B or B/A cancel out in Expressions 111 and 112. Accordingly, the measurement apparatus 40 can accurately calculate the phase error even if the measurement level of the measuring section 44 is offset, for example.

The following uses FIG. 6 to further describe why the phase error can be calculated using Expressions 15 and 16.

Expression 121 is derived from Expressions 101, 102, and 105. Expression 122 is derived from Expressions 105, 106, and 107.

$$\begin{matrix}{v}_{1}^{2} + {v}_{2}^{2} - 2 {s}_{t 1}^{2} = {s}_{t 2}^{2} & ( 121 ) \\ {s}_{t 1}^{2} = {a}^{2} + {b}^{2} = {( - \frac{{v}_{3}^{2} - {v}_{4}^{2}}{4 {s}_{t 2}} )}^{2} + {( \frac{{v}_{1}^{2} - {v}_{2}^{2}}{4 {s}_{t 2}} )}^{2} & ( 122 )\end{matrix}$$

Expression 123 is derived from Expressions 121 and 122.

$${v}_{1}^{2} + {v}_{2}^{2} - {s}_{t 1}^{2} - 2 \frac{1}{16 {s}_{t 1}^{2}} [ {( {v}_{3}^{2} - {v}_{4}^{2} )}^{2} + {( {v}_{1}^{2} - {v}_{2}^{2} )}^{2} ] = 0 \qquad ( 123 )$$

Expression 124 is obtained by multiplying both sides of Expression 123 by sₜ₁².

$${s}_{t 1}^{4} - \frac{{v}_{1}^{2} + {v}_{2}^{2}}{2} {s}_{t 1}^{2} + \frac{1}{16} [ {( {v}_{3}^{2} - {v}_{4}^{2} )}^{2} + {( {v}_{1}^{2} - {v}_{2}^{2} )}^{2} ] = 0 \qquad ( 124 )$$

By viewing Expression 124 as a quadratic equation of sₜ₁² such that (sₜ₁²)²+B×(sₜ₁²)+C=0, B and C can be calculated using Expression 125.

$$B = - \frac{{v}_{1}^{2} + {v}_{2}^{2}}{2} \\ C = \frac{1}{16} [ {( {v}_{3}^{2} - {v}_{4}^{2} )}^{2} + {( {v}_{1}^{2} - {v}_{2}^{2} )}^{2} ] \qquad ( 125 )$$

By solving for Expression 125, sₜ₁² can be expressed as shown in Expression 126.

$$\begin{matrix}{s}_{t 1}^{2} = \frac{1}{2} ( - B \pm \sqrt{{B}^{2} - 4 C} ) \\ = \frac{1}{4} ( {v}_{1}^{2} + {v}_{2}^{2} ) \pm \frac{1}{4} \sqrt{4 {v}_{1}^{2} {v}_{2}^{2} - {( {v}_{3}^{2} - {v}_{4}^{2} )}^{2}}\end{matrix} \qquad ( 126 )$$

By substituting Sₜ₁² of Expression 126 into Expression 121, sₜ₂² can be shown by Expression 127.

$$\begin{matrix}{s}_{t 2}^{2} = \frac{{v}_{1}^{2} + {v}_{2}^{2} - 2 {s}_{t 1}^{2}}{2} \\ = \frac{1}{4} ( {v}_{1}^{2} + {v}_{2}^{2} ) ∓ \frac{1}{4} \sqrt{4 {v}_{1}^{2} {v}_{2}^{2} - {( {v}_{3}^{2} - {v}_{4}^{2} )}^{2}}\end{matrix} \qquad ( 127 )$$

Here, since s_{f1}=s_{f2}=1, the amplitude error gₑᵣᵣ can be expressed as (sₜ₂/sₜ₁). Accordingly, the amplitude error estimation value can be calculated using Expressions 128 and 129. The amplitude error is calculated differently depending on if it is less than 1 or greater than or equal to 1. Here, g_{c1} represents the estimation value when the amplitude error is greater than or equal to 1, and g_{c2} represents the estimation value when the amplitude error is less than 1.

$$\begin{matrix}{g}_{c 1} = \frac{{s}_{t 2}}{{s}_{t 1}} = \sqrt{\frac{{s}_{t 2}^{2}}{{s}_{t 1}^{2}}} = \sqrt{\frac{D + E}{D - E}} = \sqrt{1 + 2 \frac{E}{D - E}} = \sqrt{1 + \frac{2}{\frac{D}{E} - 1}} & ( 128 ) \\ {g}_{c 2} = \frac{{s}_{t 1}}{{s}_{t 2}} = \sqrt{\frac{{s}_{t 1}^{2}}{{s}_{t 2}^{2}}} = \sqrt{\frac{D - E}{D + E}} = \sqrt{1 - 2 \frac{E}{D + E}} = \sqrt{1 - \frac{2}{\frac{D}{E} + 1}} & ( 129 )\end{matrix}$$

In Expressions 128 and 129, D and E can be calculated by Expression 130 below.

$$D = \frac{1}{4} ( {v}_{1}^{2} + {v}_{2}^{2} ) \\ E = \frac{1}{4} \sqrt{4 {v}_{1}^{2} {v}_{2}^{2} - {( {v}_{3}^{2} - {v}_{4}^{2} )}^{2}} \qquad ( 130 )$$

In this way, the measurement apparatus 40 can calculate the amplitude error estimation value based on Expressions 128 and 129. Furthermore, even when the overall amplitude of the output signal is multiplied by α, the values of g_{c1} and g_{c2} do not change because the numerator and denominator of D/E cancel out in Expressions 128 and 129. Accordingly, the measurement apparatus 40 can accurately calculate the amplitude error even if the measurement level of the measuring section 44 is offset, for example.

FIG. 7 shows exemplary vectors output as a result of the second error calculation process. FIG. 8 shows a magnified view near the origin point shown in FIG. 7. In the second error calculation process of step ST12, the control section 42, the measuring section 44, and the calculating section 46 of the measurement apparatus 40 perform the following processes, for example.

First, the control section 42 causes the modulation apparatus 10 to output an output signal (Sout) having three signal points in which phases of the first modulated signal (S₁) and the second modulated signal (S₂) are set to obtain a phase difference of (−θ_{c1}+180°), the amplitude of the first modulated signal (S₁) is set to a predetermined value, and the amplitude of the second modulated signal (S₂) is set to be 1 times, (1+Δvf) times, and (1−Δvf) times the amplitude of the first modulated signal.

In this case, Δvf of the present embodiment represents (1/g_{c1})−1 or (1/g_{c2})−1. If Δvf is a predetermined small amplitude value that is sufficiently less than the amplitude of the first modulated signal (S₁), then Δvf can be a value other than (1/g_{c1})−1 or (1/g_{c2})−1. Furthermore, θ_{c1} is the first phase error estimation value calculated in step ST11, g_{c1} is the first amplitude error estimation value calculated in step ST11, and g_{c2} is the second amplitude error estimation value calculated in step ST11.

The measuring section 44 measures the power of the output signal (Sout) for each of these three signal points. The calculating section 46 calculates the third amplitude error estimation value g_{c3} between the first modulated signal (S₁) and the second modulated signal (S₂) based on the power of the output signal (Sout) for each of the three signal points. More specifically, with p₀ representing the power of the output signal (Sout) output when the amplitude of the second modulated signal (S₂) is set to be 1 times the amplitude of the first modulated signal, p₁ representing the power of the output signal (Sout) output when the amplitude of the second modulated signal (S₂) is set to be (1+Δvf) times the amplitude of the first modulated signal, and p₂ representing the power of the output signal (Sout) output when the amplitude of the second modulated signal (S₂) is set to be (1−Δvf) times the amplitude of the first modulated signal, the calculating section 46 calculates the third amplitude error estimation value g_{c3} according to Expression 18 shown below.

$${g}_{c 3} = \frac{1}{1 - ( \frac{1}{{g}_{c 1}} - 1 ) \frac{{p}_{1} - {p}_{2}}{2 ( {p}_{1} + {p}_{2} - 2 {p}_{0} )}} \qquad ( 18 )$$

In this way, the measurement apparatus 40 can measure the amplitude error in a state where the amplitude error and the phase error have been partially corrected, based on the power of the output signal (Sout) at three signal points obtained by shifting the amplitude of the second modulated signal (S₂) by units of Δvf. As a result, the measurement apparatus 40 can measure the amplitude error between the first modulating section 22 and the second modulating section 24 more accurately than a simple measuring device.

In the process performed at step ST12 during the process loop, i.e. from the second performance of step ST12 onward, the control section 42 causes the modulation apparatus 10 to output an output signal (Sout) having three signal points in which phases of the first modulated signal (S₁) and the second modulated signal (S₂) are set to obtain a phase difference of (−θ_{c2}+180°), the amplitude of the first modulated signal (S₁) is set to a predetermined value, and the amplitude of the second modulated signal (S₂) is set to be 1 times, (1+Δvt) times, and (1−Δvf) times the amplitude of the first modulated signal (S₁).

In this case, Δvf of the present embodiment represents (1/g_{c3})−1. If Δvf is a predetermined small amplitude value that is sufficiently less than the amplitude of the first modulated signal (S₁), then Δvf can be a value other than (1/g_{c3})−1. Furthermore, θ_{c2} is the second phase error estimation value calculated in the immediately prior step ST13, and g_{c3} is the third amplitude error estimation value calculated in the immediately prior step ST12.

If steps ST12 and ST13 are performed in the opposite order, in the first performance of step ST12, the control section 42 causes the modulation apparatus 10 to output an output signal (Sout) having three signal points in which phases of the first modulated signal (S₁) and the second modulated signal (S₂) are set to obtain a phase difference of (−θ_{c2}+180°, the amplitude of the first modulated signal (S₁) is set to a predetermined value, and the amplitude of the second modulated signal (S₂) is set to be 1 times, (1+Δvf) times, and (1−Δvf) times the amplitude of the first modulated signal (S₁).

In this case, Δvf represents (1/g_{c1})−1 or (1/g_{c2})−1. If Δvf is a predetermined small amplitude value that is sufficiently less than the amplitude of the first modulated signal (S₁), then Δvf can be a value other than (1/g_{c1})−1 or (1/g_{c2})−1. Furthermore, θ_{c2} is the second phase error estimation value calculated in the immediately prior step ST13.

The following uses FIG. 8 to further describe why the amplitude error can be calculated using Expression 18.

In FIG. 8, sₜ₁ represents the amplitude of the first modulated signal (S₁) at the output end and sₜ₂ represents the amplitude of the second modulated signal (S₂) at the output end.

In FIG. 8, the phase θ_{f1} of the first modulated signal (S₁) at the input end is set to 0°, and the phase θ_{f2} of the second modulated signal (S₂) at the input end is set to −θ_{c1}+180°.

In FIG. 8, the amplitude s_{f1} of the first modulated signal (S₁) at the input end is set to 1, and the amplitude s_{f2} of the second modulated signal (S₂) at the input end is set to 1, 1+Δvf, and 1−Δvf. Here, Δvf represents (1/g_{c1})−1 or (1/g_{c2})−1. If Δvf is a predetermined small amplitude value that is sufficiently less than the amplitude of the first modulated signal (S₁), then Δvf can be a value other than (1/g_{c1})−1 or (1/g_{c2})−1.

In FIG. 8, O-Q0 represents the vector of the output signal when s_{f2}=1 and has an amplitude v₀, O-Q1 represents the vector of the output signal when s_{f2}=1+Δvf and has an amplitude v₁, and O-Q2 represents the vector of the output signal when s_{f2}=1−Δvf and has an amplitude v₂.

Furthermore, Δvt represents the length of Q0-Q1, −Δvt represents the length of Q0-Q2, Q11 represents an intersection point between the line Q1-Q2 and a line descending orthogonally therefrom through the origin O, “a” represents the distance of O-Q11, and “b” represents the distance Q11-Q0.

Expressions 201, 202, and 203 are derived from FIG. 8.

v₀²=a²+b² (201)

v₁²=a²+(b+Δv₁)²=a²+b²+Δv₁²+2bΔv₁ (202)

v₂²=a²+(b−Δv₁)²=a²+b²+Δv₁²−2bΔv₁ (203)

Expressions 204 and 205 are derived from Expressions 201 to 203.

v₁²+v₂²−2v₀²=2Δvₜ² (204)

v₁²−v₂²=4bΔv₁ (205)

Expression 206 is derived from Expressions 204 and 205.

$$\frac{b}{Δ {v}_{t}} = \frac{b Δ {v}_{t}}{Δ {v}_{t}^{2}} = \frac{\frac{1}{4} ( {v}_{1}^{2} - {v}_{2}^{2} )}{\frac{1}{2} ( {v}_{1}^{2} + {v}_{2}^{2} - 2 {v}_{0}^{2} )} = \frac{{v}_{1}^{2} - {v}_{2}^{2}}{2 ( {v}_{1}^{2} + {v}_{2}^{2} - 2 {v}_{0}^{2} )} \qquad ( 206 )$$

Here, the amplitude error gₑᵣᵣ is Δvt/Δvf, the amplitude sₜ₂ of the second modulated signal (S₂) at the output end is expressed as gb×s_{f2}, and the relationship between the amplitude sₜ₁ of the first modulated signal (S₁) at the output end and amplitude sₜ₂ of the second modulated signal (S₂) at the output end is expressed as sₜ₁=sₜ₂−b.

The amplitude s_{f2}′ set for the second modulated signal (S₂) is then changed to match the amplitude at the output end, i.e. such that sₜ₁=sₜ₂′. In this case, s_{f2}′ is shown by Expression 207 below.

Expression 207:

Accordingly, since s_{f1}=s_{f2}=1, the amplitude error estimation value g_{c3} can be calculated as shown in Expression 208 below.

$${s}_{f 2}^{′} = \frac{{s}_{t 2} - b}{{g}_{err}} = {s}_{f 2} - \frac{Δ {v}_{f}}{Δ {v}_{t}} b \qquad ( 207 )$$

Here, v₀² represents the power p₀ of the output signal when s_{f2}=1, v₁² represents the power p₁ of the output signal when s_{f2}=1+Δvf, and v₂² represents the power p₂ of the output signal when s_{f2}=1−Δvf.

In this way, the measurement apparatus 40 can calculate the amplitude error estimation value from Expression 208. Furthermore, even when the overall amplitude of the output signal is multiplied by α, the value of g_{c3} does not change because the numerator and denominator of s_{f1}/s_{f2}′ cancel out in Expression 208. Accordingly, the measurement apparatus 40 can accurately calculate the amplitude error even if the measurement level of the measuring section 44 is offset, for example.

FIG. 9 shows exemplary vectors output as a result of the third error calculation process. In the third error calculation process of step ST13, the control section 42, the measuring section 44, and the calculating section 46 of the measurement apparatus 40 perform the following processes, for example.

First, the control section 42 causes the modulation apparatus 10 to output an output signal (Sout) having three signal points in which the amplitude of the first modulated signal (S₁) is set to a predetermined value, the amplitude of the second modulated signal (S₂) is set to be (1/g_{c3}) times the amplitude of the first modulated signal, and phases of the first modulated signal (S₁) and the second modulated signal (S₂) are set to obtain phase differences of (−θ_{c1}+180°), (−θ_{c1}+Δθ+180°), and (−θ_{c1}−Δθ+180°).

Here, Δθ represents a predetermined small angle, such as 1°, θ_{c1} is the first phase error estimation value calculated in step ST11, and g_{c3} is the third amplitude error estimation value calculated in step ST12.

The measuring section 44 measures the power of the output signal (Sout) for each of these three signal points. The calculating section 46 calculates the second phase error estimation value θ_{c2} between the first modulated signal (S₁) and the second modulated signal (S₂) based on the power of the output signal (Sout) for each of the three signal points. More specifically, with p₀ representing the power of the output signal (Sout) output when the phase difference is set to (−θ_{c1}+180°), p₁ representing the power of the output signal (Sout) output when the phase difference is set to (−θ_{c1}+Δθ+180°), and p₂ representing the power of the output signal (Sout) output when the phase difference is set to (−θ_{c1}−Δθ+180°), the calculating section 46 calculates the second phase error estimation value θ_{c2} according to Expression 19 shown below.

$${θ}_{c 2} = {θ}_{c 1} + Δθ \frac{{p}_{1} - {p}_{2}}{2 ( {p}_{1} + {p}_{2} - 2 {p}_{0} )} \qquad ( 19 )$$

In the process performed at step ST13 during the process loop, the control section 42 causes the modulation apparatus 10 to output an output signal (Sout) having three signal points in which the amplitude of the first modulated signal (S₁) is set to a predetermined value, the amplitude of the second modulated signal (S₂) is set to be (1/g_{c3}) times the amplitude of the first modulated signal, and phases of the first modulated signal (S₁) and the second modulated signal (S₂) are set to obtain phase differences of (−θ_{c2}+180°), (−θ_{c2}+Δθ+180°), and (−θ_{c2}−Δθ+180Δ).

In this case, θ_{c2} is the second phase error estimation value calculated in the immediately prior step ST13, and g_{c3} is the third amplitude error estimation value calculated in the immediately prior step ST12.

If steps ST12 and ST13 are performed in the opposite order, in the first performance of step ST13, the control section 42 causes the modulation apparatus 10 to output an output signal (Sout) having three signal points in which the amplitude of the first modulated signal (S₁) is set to a predetermined value, the amplitude of the second modulated signal (S₂) is set to be 1 times the amplitude of the first modulated signal, and phases of the first modulated signal (S₁) and the second modulated signal (S₂) are set to obtain phase differences of (−θ_{c1}+180°), (−θ_{c1}+Δθ+180°), and (−θ_{c1}−Δθ+180°). Here, θ_{c1} is the first phase error estimation value calculated in step ST11.

In this case, the control section 42 may set the amplitude of the second modulated signal (S₂) to be (1/g_{c1}) times or (1/g_{c2}) times the amplitude of the first modulated signal (S₁), or to be some other multiple of the amplitude of the first modulated signal (S₁). Furthermore, g_{c1} is the first amplitude error estimation value calculated in step ST11 and g_{c2} is the second amplitude error estimation value calculated in step ST11.

The following uses FIG. 9 to further describe why the phase error can be calculated using Expression 19.

In FIG. 9, sₜ₁ represents the amplitude of the first modulated signal (S₁) at the output end and sₜ₂ represents the amplitude of the second modulated signal (S₂) at the output end.

In FIG. 9, the amplitude s_{f1} of the first modulated signal (S₁) at the input end is set to 1, and the amplitude s_{f2} of the second modulated signal (S₂) at the input end is set to 1/g_{c3}.

In FIG. 9, the phase θ_{f1} of the first modulated signal (S₁) at the input end is set to 0°, and the phase θ_{f2} of the second modulated signal (S₂) at the input end is set to −θ_{c1}+180°, −θ_{c1}+Δθ+180°, and −θ_{c1}−Δθ+180°. Here, Δθ is a small angle, such as 1°.

In FIG. 9, O-Q0 represents one of the vector of the output signal when θ_{f2}=−θ_{c1}+180°, the vector of the output signal when θ_{f2}=−θ_{c1}+Δθ+180°, and the vector of the output signal when θ_{f2}=−θ_{c1}−Δθ+180°. Furthermore, the amplitude of the vector of the output signal when θ_{f2}=−θ_{c1}+180° is v₀, the amplitude of the vector of the output signal when θ_{f2}=−θ_{c1}+Δθ+180° is v₁, and the amplitude of the vector of the output signal when θ_{f2}=−θ_{c1}−Δθ+180° is v₂.

Furthermore, O-Q12 represents the vector of the first modulated signal (S₁) at the output end, and O-Q13 represents the vector of the first modulated signal (S₁) at the output end after being given a length of sₜ₁+sₜ₂.

Furthermore, Q14 represents the intersection point between the X-axis and a line orthogonal to the line Q0-Q13 passing through Q0, a₀ represents the length of Q0-Q14, and b₀ represents the length of Q0-Q13.

Yet further, Q11 represents the intersection point between the extension of the line Q0-Q13 and a line descending orthogonally therefrom through the origin O, c₀ represents the length of O-Q11, and d₀ represents the length of Q11-Q0.

Expressions 301 and 302 shown below are derived from FIG. 9.

a₀²=(2sₜ₂ sin(−θ/2))²≈sₜ₂²θ² (301)

a₀²+b₀²=(2sₜ₂)²=4sₜ₂² (302)

Here, θ=θₑᵣᵣ−θ_{c1}. In Expressions 301 and 302, sin(θ)≠θ is used to approximate θ=θₑᵣᵣ−θ_{c1}≠0. Expression 303 is derived from Expressions 301 and 302.

b₀²=4sₜ₂²−a₀²=sₜ₂²(4−θ²) (303)

Since the triangular shape of Q0-Q13-Q14 is analogous to the triangular shape Q11-O-Q14, Expressions 304 and 305 are derived.

$$\begin{matrix}{c}_{0}^{2} = {( \frac{{s}_{t 1} + {s}_{t 2}}{2 {s}_{t 2}} {a}_{0} )}^{2} = {( \frac{{s}_{t 1} + {s}_{t 2}}{2} )}^{2} {θ}^{2} & ( 304 ) \\ {b}_{0} + {d}_{0} = \frac{{s}_{t 1} + {s}_{t 2}}{2 {s}_{t 2}} {b}_{0} & ( 305 )\end{matrix}$$

Expression 306 is derived from Expressions 303 and 305.

$${d}_{0}^{2} = {( \frac{{s}_{t 1} + {s}_{t 2}}{2 {s}_{t 2}} - 1 )}^{2} {b}_{0} = {( \frac{{s}_{t 1} - {s}_{t 2}}{2} )}^{2} ( 4 - {θ}^{2} ) \qquad ( 306 )$$

Expression 307 is derived from Expressions 304 and 306.

$$\begin{matrix}{v}_{0}^{2} = {c}_{0}^{2} + {d}_{0}^{2} \\ = {( \frac{{s}_{t 1} - {s}_{t 2}}{2} θ )}^{2} + {( \frac{{s}_{t 1} - {s}_{t 2}}{2} )}^{2} ( 4 - {θ}^{2} ) \\ = [ \frac{1}{4} {( {s}_{t 1} + {s}_{t 2} )}^{2} - \frac{1}{4} {( {s}_{t 1} - {s}_{t 2} )}^{2} ] {θ}^{2} + {( {s}_{t 1} - {s}_{t 2} )}^{2} \\ = \frac{1}{4} [ ( {s}_{t 1} + {s}_{t 2} + {s}_{t 1} - {s}_{t 2} ) ( {s}_{t 1} + {s}_{t 2} - {s}_{t 1} + {s}_{t 2} ) ] {θ}^{2} + \\ {( {s}_{t 1} - {s}_{t 2} )}^{2} \\ = \frac{1}{4} 2 {s}_{t 1} 2 {s}_{t 2} {θ}^{2} + {( {s}_{t 1} - {s}_{t 2} )}^{2} \\ = {s}_{t 1} {s}_{t 2} {θ}^{2} + {( {s}_{t 1} - {s}_{t 2} )}^{2}\end{matrix} \qquad ( 307 )$$

Similarly, θ_{f2} is calculated when θ+Δθ is set and when θ−Δθ is set. Expression 308 is derived by substituting θ+Δθ and θ−Δθ for the θ of Expression 307.

v₁²=sₜ₂sₜ₂(θ+Δθ)²+(sₜ₁−sₜ₂)²=sₜ₁sₜ₂(θ²+Δθ²+2θΔθ)+(sₜ₁−sₜ₂)²

v₂²=sₜ₁sₜ₂(θ−Δθ)²+(sₜ₁−sₜ₂)²=sₜ₁sₜ₂(θ²+Δθ²−2θΔθ)+(sₜ₁−sₜ₂)² (308)

Expressions 309 and 310 are derived from Expressions 307 and 308.

v₁²+v₁²−2v₀²=2sₜ₁sₜ₂Δθ² (309)

v₁²−v₂²=sₜ₁sₜ₂4θΔθ (310)

The ratio between θ and Δθ can be calculated using Expression 311, which is derived from Expressions 309 and 310.

$$\frac{θ}{Δθ} = \frac{θΔθ}{{Δθ}^{2}} = \frac{{v}_{1}^{2} - {v}_{2}^{2}}{2 ( {v}_{1}^{2} + {v}_{2}^{2} - 2 {v}_{0}^{2} )} \qquad ( 311 )$$

Since θₑᵣᵣ−θ_{c1}=θ, the estimation value θ_{c2} of θₑᵣᵣ can be calculated using Expression 312.

$${θ}_{c 2} = θ err = {θ}_{c 1} + θ = {θ}_{c 1} + Δθ \frac{θ}{Δθ} = {θ}_{c 1} + Δθ \frac{{v}_{1}^{2} - {v}_{2}^{2}}{2 ( {v}_{1}^{2} + {v}_{2}^{2} - 2 {v}_{0}^{2} )} \qquad ( 312 )$$

Here, v₀² represents the power p₀ of the output signal when θ_{f2}=−θ_{c1}+180°, v₁² represents the power p₁ of the output signal when θ_{f2}=−θ_{c1}+Δθ180°, and v₂² represents the power p₂ of the output signal when θ_{f2}=−θ_{c1}−Δθ+180°.

In this way, the measurement apparatus 40 can calculate the phase error estimation value from Expression 312. Furthermore, even when the overall amplitude of the output signal is multiplied by α, the value of θ_{c2} does not change because the terms in the numerator and denominator multiplied by Δθ cancel out in Expression 312. Accordingly, the measurement apparatus 40 can accurately calculate the amplitude error even if the measurement level of the measuring section 44 is offset, for example.

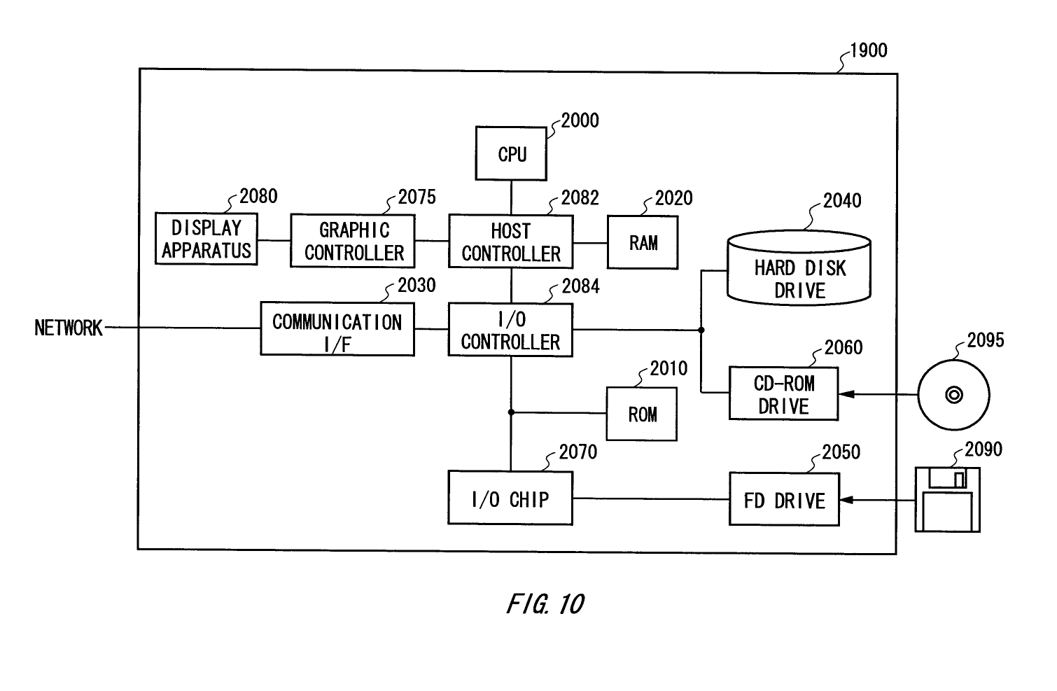

FIG. 10 shows an example of a hardware configuration of a computer 1900 according to the present embodiment. The computer 1900 according to the present embodiment is provided with a CPU peripheral including a CPU 2000, a RAM 2020, a graphic controller 2075, and a display apparatus 2080, all of which are connected to each other by a host controller 2082; an input/output section including a communication interface 2030, a hard disk drive 2040, and a CD-ROM drive 2060, all of which are connected to the host controller 2082 by an input/output controller 2084; and a legacy input/output section including a ROM 2010, a flexible disk drive 2050, and an input/output chip 2070, all of which are connected to the input/output controller 2084.

The host controller 2082 is connected to the RAM 2020 and is also connected to the CPU 2000 and graphic controller 2075 accessing the RAM 2020 at a high transfer rate. The CPU 2000 operates to control each section based on programs stored in the ROM 2010 and the RAM 2020. The graphic controller 2075 acquires image data generated by the CPU 2000 or the like on a frame buffer disposed inside the RAM 2020 and displays the image data in the display apparatus 2080. Instead, the graphic controller 2075 may internally include the frame buffer storing the image data generated by the CPU 2000 or the like.

The input/output controller 2084 connects the communication interface 2030 serving as a relatively high speed input/output apparatus, and the hard disk drive 2040, and the CD-ROM drive 2060 to the host controller 2082. The communication interface 2030 communicates with other apparatuses via a network. The hard disk drive 2040 stores the programs and data used by the CPU 2000 housed in the computer 1900. The CD-ROM drive 2060 reads the programs and data from a CD-ROM 2095 and provides the read information to the hard disk drive 2040 via the RAM 2020.

Furthermore, the input/output controller 2084 is connected to the ROM 2010, and is also connected to the flexible disk drive 2050 and the input/output chip 2070 serving as a relatively high speed input/output apparatus. The ROM 2010 stores a boot program performed when the computer 1900 starts up, a program relying on the hardware of the computer 1900, and the like. The flexible disk drive 2050 reads programs or data from a flexible disk 2090 and supplies the read information to the hard disk drive 2040 via the RAM 2020. The input/output chip 2070 connects the flexible disk drive 2050 to the input/output controller 2084 along with each of the input/output apparatuses via, a parallel port, a serial port, a keyboard port, a mouse port, or the like.

The programs provided to the hard disk drive 2040 via the RAM 2020 are stored in a storage medium, such as the flexible disk 2090, the CD-ROM 2095, or an IC card, and provided by a user. The programs are read from storage medium, installed in the hard disk drive 2040 inside the computer 1900 via the RAM 2020, and performed by the CPU 2000.

These programs are installed in the computer 1900 to make the computer 1900 function as the calculating section 46 of the measurement apparatus 40.

The information processes recorded in these programs are read by the computer 1900 to cause the computer 1900 to function as the software and hardware described above, which is exemplified by the calculating section 46 of the measurement apparatus 40. With these specific sections, a unique calculating section 46 suitable for an intended use can be configured by realizing the calculations or computations appropriate for the intended use of the computer 1900 of the present embodiment.

For example, if there is communication between the computer 1900 and an external apparatus or the like, the CPU 2000 performs the communication program loaded in the RAM 2020, and provides the communication interface 2030 with communication processing instructions based on the content of the process recorded in the communication program. The communication interface 2030 is controlled by the CPU 2000 to read the transmission data stored in the transmission buffer area or the like on the storage apparatus, such as the RAM 2020, the hard disc 2040, the flexible disk 2090, or the CD-ROM 2095, and send this transmission data to the network, and to write data received from the network onto a reception buffer area on the storage apparatus. In this way, the communication interface 2030 may transmit data to and from the storage apparatus through DMA (Direct Memory Access). As another possibility, the CPU 2000 may transmit the data by reading the data from the storage apparatus or communication interface 2030 that are the origins of the transmitted data, and writing the data onto the communication interface 2030 or the storage apparatus that are the transmission destinations.

The CPU 2000 may perform various processes on the data in the RAM 2020 by reading into the RAM 2020, through DMA transmission or the like, all or a necessary portion of the database or files stored in the external apparatus such as the hard disk drive 2040, the CD-ROM drive 2060, the CD-ROM 2095, the flexible disk drive 2050, or the flexible disk 2090. The CPU 2000 writes the processed data back to the external apparatus through DMA transmission or the like. In this process, the RAM 2020 is considered to be a section that temporarily stores the content of the external storage apparatus, and therefore the RAM 2020, the external apparatus, and the like in the present embodiment are referred to as a memory, a storage section, and a storage apparatus. The variety of information in the present embodiment, such as the variety of programs, data, tables, databases, and the like are stored on the storage apparatus to become the target of the information processing. The CPU 2000 can hold a portion of the RAM 2020 in a cache memory and read from or write to the cache memory. With such a configuration as well, the cache memory serves part of the function of the RAM 2020, and therefore the cache memory is also included with the RAM 2020, the memory, and/or the storage apparatus in the present invention, except when a distinction is made.

The CPU 2000 executes the various processes such as the computation, information processing, condition judgment, searching for/replacing information, and the like included in the present embodiment for the data read from the RAM 2020, as designated by the command sequence of the program, and writes the result back onto the RAM 2020. For example, when performing condition judgment, the CPU 2000 judges whether a variable of any type shown in the present embodiment fulfills a condition of being greater than, less than, no greater than, no less than, or equal to another variable or constant. If the condition is fulfilled, or unfulfilled, depending on the circumstances, the CPU 2000 branches into a different command sequence or acquires a subroutine.

The CPU 2000 can search for information stored in a file in the storage apparatus, the database, and the like. For example, if a plurality of entries associated respectively with a first type of value and a second type of value are stored in the storage apparatus, the CPU 2000 can search for entries fulfilling a condition designated by the first type of value from among the plurality of entries stored in the storage apparatus. The CPU 2000 can then obtain the second type of value associated with the first type of value fulfilling the prescribed condition by reading the second type of value stored at the same entry.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

The programs and modules shown above may also be stored in an external storage medium. The flexible disk 2090, the CD-ROM 2095, an optical storage medium such as a DVD or CD, a magneto-optical storage medium, a tape medium, a semiconductor memory such as an IC card, or the like can be used as the storage medium. Furthermore, a storage apparatus such as a hard disk or RAM that is provided with a server system connected to the Internet or a specialized communication network may be used to provide the programs to the computer 1900 via the network.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A measurement apparatus for measuring an error of a modulation apparatus that outputs an output signal obtained as a sum of a first modulated signal output from a first modulating section and a second modulated signal output from a second modulating section, the measurement apparatus comprising:
a control section that causes the modulation apparatus to output an output signal having at least three different signal points;
a measuring section that measures power of the output signal for each of the at least three signal points; and
a calculating section that calculates at least one of an amplitude error and a phase error between the first modulated signal and the second modulated signal, based on the power of the output signal for each of the at least three signal points.

2. The measurement apparatus according to claim 1, wherein
the modulation apparatus is a LINC modulation apparatus that outputs an output signal corresponding to a designated amplitude and a designated phase.

3. The measurement apparatus according to claim 1, wherein
the control section causes the modulation apparatus to output an output signal having at least four signal points in which amplitudes of the first modulated signal and the second modulated signal are each set to a predetermined value and phases of the first modulated signal and the second modulated signal are set to different values to obtain different phase differences therebetween.

4. The measurement apparatus according to claim 3, wherein
the control section causes the modulation apparatus to output an output signal having four signal points in which the amplitudes of the first modulated signal and the second modulated signal are each set to the same predetermined value and the phases of the first modulated signal and the second modulated signal are set to obtain phase differences of 0°, 180°, 90°, and 270° therebetween,
the measuring section measures the power of the output signal for each of the four signal points, and
the calculating section calculates an amplitude error estimation value and a phase error estimation value between the first modulated signal and the second modulated signal, based on the power of the output signal for each of the four signal points.

5. The measurement apparatus according to claim 4, wherein
with p₁ representing the power of the output signal when the phase difference is set to 0°, p₂ representing the power of the output signal when the phase difference is set to 180°, p₃ representing the power of the output signal when the phase difference is set to 90°, and p₄ representing the power of the output signal when the phase difference is set to 270°, the calculating section calculates a first phase error estimation value θ_{c1} according to Expressions 11 and 12,
Expressions 11 and 12 are defined as:
$$\begin{matrix}{θ}_{c 1} = {θ}_{m 1} = \{ \begin{matrix}{tan}^{- 1} ( - \frac{A}{B} ) … B \geq 0 , A \geq 0 \\ {tan}^{- 1} ( - \frac{A}{B} ) + 180 … B < 0 \\ {tan}^{- 1} ( - \frac{A}{B} ) + 360 … B \geq 0 , A < 0\end{matrix} & ( 11 ) \\ {θ}_{c 1} = 90 - {θ}_{m 2} = \{ \begin{matrix}90 - {tan}^{- 1} ( \frac{B}{A} ) … A \geq 0 \\ 270 - {tan}^{- 1} ( \frac{B}{A} ) … A < 0\end{matrix} & ( 12 )\end{matrix}$$
the calculating section performs the calculation using Expression 11 when |B|>|A| and performs the calculation using Expression 12 when |B|≦|A|,
in Expressions 11 and 12, A and B are calculated as shown by Expressions 13 and 14, and
Expressions 13 and 14 are defined as:
A=p₃−p₄ (13)
B=p₁−p₂ (14)

6. The measurement apparatus according to claim 4, wherein
with p₁ representing the power of the output signal when the phase difference is set to 0°, p₂ representing the power of the output signal when the phase difference is set to 180°, p₃ representing the power of the output signal when the phase difference is set to 90°, and p₄ representing the power of the output signal when the phase difference is set to 270°, the calculating section calculates at least one of a first amplitude error estimation value g_{c1} and a second amplitude error estimation value g_{c2} according to Expressions 15 and 16,
Expressions 15 and 16 are defined as:
$$\begin{matrix}{g}_{c 1} = \sqrt{1 + \frac{2}{\frac{D}{E} - 1}} & ( 15 ) \\ {g}_{c 2} = \sqrt{1 - \frac{2}{\frac{D}{E} + 1}} & ( 16 )\end{matrix}$$
in Expressions 15 and 16, D and E are calculated as shown by Expression 17, and
Expressions 17 is defined as:
$$D = \frac{1}{4} ( {p}_{1} + {p}_{2} ) \\ E = \frac{1}{4} \sqrt{4 {p}_{1} {p}_{2} - {( {p}_{3} - {p}_{4} )}^{2}} \qquad ( 17 )$$

7. The measurement apparatus according to claim 1, wherein
the control section causes the modulation apparatus to output an output signal having at least three signal points in which phases of the first modulated signal and second modulated signal are set to create a predetermined phase difference therebetween and different amplitudes are set for the first modulated signal and the second modulated signal.

8. The measurement apparatus according to claim 1, wherein
the control section causes the modulation apparatus to output an output signal having at least three signal points in which amplitudes of the first modulated signal and second modulated signal are set to a predetermined value and phases of the first modulated signal and the second modulated signal are set to obtain different phase differences.

9. The measurement apparatus according to claim 4, wherein
the control section causes the modulation apparatus to output an output signal having three signal points in which phases of the first modulated signal and the second modulated signal are set to obtain a phase difference of (−θ_{c1}+180°), the amplitude of the first modulated signal is set to a predetermined value, and the amplitude of the second modulated signal is set to be 1 times, (1+Δvf) times, and (1−Δvf) times the amplitude of the first modulated signal,
Δvf represents a predetermined small amplitude that is less than 1,
the measuring section measures the power of the output signal for each of the three signal points, and
the calculating section calculates a third amplitude error estimation value between the first modulated signal and the second modulated signal, based on the power of the output signal for each of the three signal points.

10. The measurement apparatus according to claim 9, wherein
with p₀ representing the power of the output signal when the amplitude of the second modulated signal is set to be 1 times the amplitude of the first modulated signal, p₁ representing the power of the output signal when the amplitude of the second modulated signal is set to be (1+Δvf) times the amplitude of the first modulated signal, and p₂ representing the power of the output signal when the amplitude of the second modulated signal is set to be (1−Δvf) times the amplitude of the first modulated signal, the calculating section calculates a third amplitude error estimation value g_{c3} according to Expression 18, and
Expression 18 is defined as:
$${g}_{c 3} = \frac{1}{1 - ( \frac{1}{{g}_{c 1}} - 1 ) \frac{{p}_{1} - {p}_{2}}{2 ( {p}_{1} + {p}_{2} - 2 {p}_{0} )}} \qquad ( 18 )$$

11. The measurement apparatus according to claim 10, wherein
the control section causes the modulation apparatus to output an output signal having three signal points in which the amplitude of the first modulated signal is set to a predetermined value, the amplitude of the second modulated signal is set to be (1/g_{c3}) times the amplitude of the first modulated signal, and the phases of the first modulated signal and the second modulated signal are set to obtain phase differences of (−θ_{c1}+180°), (−θ_{c1}+Δθ+180°), and (−θ_{c1}−Δθ+180°),
Δθ represents a predetermined small angle,
the measuring section measures the power of the output signal for each of the three signal points, and
the calculating section calculates a second phase error estimation value between the first modulated signal and the second modulated signal, based on the power of the output signal for each of the three signal points.

12. The measurement apparatus according to claim 6, wherein
the control section causes the modulation apparatus to output an output signal having three signal points in which the amplitude of the first modulated signal is set to a predetermined value, the amplitude of the second modulated signal is set to be (1/g_{c1}) times or (1/g_{c2}) times the amplitude of the first modulated signal, and the phases of the first modulated signal and the second modulated signal are set to obtain phase differences of (−θ_{c1}+180°), (−θ_{c1}+Δθ+180°), and (−θ_{c1}−Δθ+180°),
Δθ represents a predetermined small angle,
the measuring section measures the power of the output signal for each of the three signal points, and
the calculating section calculates a second phase error estimation value between the first modulated signal and the second modulated signal, based on the power of the output signal for each of the three signal points.

13. The measurement apparatus according to claim 11, wherein
with p₀ representing the power of the output signal when the phase difference is set to (−θ_{c1}+180°), p₁ representing the power of the output signal when the phase difference is set to (−θ_{c1}+Δθ+180°), and p₂ representing the power of the output signal when the phase difference is set to (−θ_{c1}−Δθ+180°), the calculating section calculates the second phase error estimation value θ_{c2} according to Expression 19, and
Expression 19 is defined as:
$${θ}_{c 2} = {θ}_{c 1} + Δθ \frac{{p}_{1} - {p}_{2}}{2 ( {p}_{1} + {p}_{2} - 2 {p}_{0} )} \qquad ( 19 )$$

14. The measurement apparatus according to claim 13, wherein
the control section causes the modulation apparatus to output an output signal having three signal points in which the phases of the first modulated signal and the second modulated signal are set to obtain a phase difference of (−θ_{c2}+180°), the amplitude of the first modulated signal is set to a predetermined value, and the amplitude of the second modulated signal is set to be 1 times, (1+Δvf) times, and (1−Δvf) times the amplitude of the first modulated signal,
Δvf represents a predetermined small amplitude that is less than 1,
the measuring section measures the power of the output signal for each of the three signal points, and
the calculating section calculates a third amplitude error estimation value between the first modulated signal and the second modulated signal, based on the power of the output signal for each of the three signal points.

15. A recording medium storing thereon a program that causes a computer to function as the calculating section provided in the measurement apparatus according to claim 1.

16. A measurement method for measuring an error of a modulation apparatus that outputs an output signal obtained as a sum of a first modulated signal output from a first modulating section and a second modulated signal output from a second modulating section, the measurement method comprising:
causing the modulation apparatus to output an output signal having at least three different signal points;
measuring power of the output signal for each of the at least three signal points; and
calculating at least one of an amplitude error and a phase error between the first modulated signal and the second modulated signal, based on the power of the output signal for each of the at least three signal points.
